(19) United States
(12) Patent Application Publication
(10) Pub. No.: US 2025/0221066 A1
(43) Pub. Date: Jul. 3, 2025

(54) DIGITAL X-RAY DETECTOR

(71) Applicant: LG Display Co., Ltd., Seoul (KR)

(72) Inventors: Soyang CHOI, Paju-si (KR); Yubeen LIM, Paju-si (KR); Youngjin YI, Paju-si (KR); HyeJi JEON, Paju-si (KR)

(73) Assignee: LG Display Co., Ltd., Seoul (KR)

(21) Appl. No.: 18/936,430

(22) Filed: Nov. 4, 2024

(30) Foreign Application Priority Data
Dec. 28, 2023 (KR) 10-2023-0194252

(51) Int. Cl. H01L 27/146

(52) U.S. Cl. CPC H10F 39/8027; H10F 39/189; H10F 39/80373; H10F 39/811

(57) ABSTRACT

A digital X-ray detector includes a pin diode having a first electrode, a second electrode disposed on the first electrode, and a photoconductive layer disposed between the first electrode and the second electrode. The digital X-ray detector further includes a vertical transistor disposed on a side surface of the photoconductive layer to overlap with the first electrode. Accordingly, it is possible to improve the photo current of the digital X-ray detector.

### CROSS-REFERENCE TO RELATED APPLICATION

This application claims priority to Korean Patent Application No. 10-2023-0194252, filed in the Republic of Korea on Dec. 28, 2023, the entire contents of which is hereby expressly incorporated by reference into the present application.

### BACKGROUND

### Field

Embodiments of the present disclosure relate to a digital X-ray detector.

### Discussion of Related Art

One of X-ray inspection methods used for medical purposes is a film printing method.

In the case of the film printing method, since a result can be checked only by shooting a film and then performing a printing process, it takes a lot of time to check the result.

Recently, a digital X-ray detector (DXD) using a thin film transistor has been developed and is widely used for medical purposes.

The digital X-ray detector is a device which detects the amount of X-rays transmitted through a subject and displays the internal state of the subject to the outside through a display, and can be referred to as an X-ray detection system.

The digital X-ray detector has advantages of being able to display the internal structure of the subject without using a separate film and photo paper and of being able to check the result in real time immediately after X-ray shooting.

The X-ray detection system can include an X-ray, a scintillator and an X-ray detection device. Light from the X-ray can pass through the subject.

The X-ray light that passes through the subject can pass through the scintillator. The X-ray light that passes through the scintillator can reach the X-ray detection device.

The X-ray detection device can generate an X-ray image by sensing X-ray light that has passed through the scintillator.

The X-ray detection device can include a pin diode. The larger the area of a photoconductive layer included in the pin diode is, the better the quality of the X-ray image is.

### SUMMARY OF THE DISCLOSURE

Embodiments of the present disclosure can provide a digital X-ray detector capable of improving photo current.

Embodiments of the present disclosure can provide a digital X-ray detector with an improved area of a photoconductive layer.

Embodiments of the present disclosure can provide a digital X-ray detector having a structure capable of protecting a transistor from external light.

Embodiments of the present disclosure can provide a digital X-ray detector capable of low power consumption as photo current is improved.

Embodiments of the present disclosure can provide a digital X-ray detector including: a substrate; a pin diode including a first electrode, a second electrode disposed on the first electrode, and a photoconductive layer disposed between the first electrode and the second electrode; and a vertical transistor disposed on a side surface of the photoconductive layer to overlap with the first electrode.

The vertical transistor can include a source electrode disposed in contact with the first electrode, an active layer disposed to overlap with the source electrode, a gate electrode disposed on a side surface of the active layer, and a drain electrode disposed in contact with the active layer.

The active layer can be disposed on the first electrode.

According to the embodiments of the present disclosure, it is possible to provide a digital X-ray detector capable of improving photo current.

According to the embodiments of the present disclosure, it is possible to provide a digital X-ray detector with an improved area of a photoconductive layer.

According to the embodiments of the present disclosure, it is possible to provide a digital X-ray detector having a structure capable of protecting a transistor from external light.

According to the embodiments of the present disclosure, it is possible to provide a digital X-ray detector capable of low power consumption as photo current is improved.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a configuration diagram of an X-ray detection system according to an embodiment of the present disclosure.

FIG. 2 is a configuration diagram of a digital X-ray detector according to an embodiment of the present disclosure.

FIG. 3 is a diagram of a detection circuit according to the embodiment of the present disclosure.

FIG. 4 is a plan view of a detection circuit disposed in a digital X-ray detection panel according to an embodiment of the present disclosure.

FIG. 5 is a cross-sectional view of the detection circuit disposed in the digital X-ray detection panel according to the embodiment of the present disclosure.

FIG. 6 is a plan view of a detection circuit disposed in a digital X-ray detection panel according to an embodiment of the present disclosure.

FIG. 7 is a cross-sectional view of the detection circuit disposed in the digital X-ray detection panel according to the embodiment of the present disclosure.

FIG. 8 is a plan view of a digital X-ray detection panel according to an embodiment of the present disclosure.

FIG. 9 is a cross-sectional view of the digital X-ray detection panel according to the embodiment of the present disclosure.

FIG. 10 shows experimental data on photo current according to the embodiment of the present disclosure.

FIG. 11 is a cross-sectional view of a scan transistor according to the embodiment of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” can be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may.”

Hereinafter, various embodiments of the present disclosure will be described in detail with reference to accompanying drawings. All the components of each device, apparatus, and system according to all embodiments of the present disclosure are operatively coupled and configured.

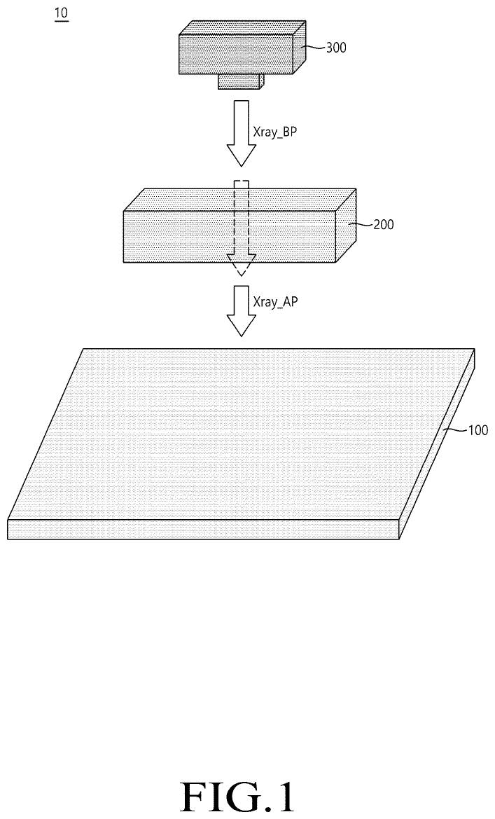

FIG. 1 is a configuration diagram of an X-ray detection system 10 according to an embodiment of the present disclosure.

Referring to FIG. 1, the X-ray detection system 10 can include a digital X-ray detector 100 and an X-ray generator 300.

The X-ray generator 300 can emit X-rays. Here, X-rays can be electromagnetic waves that have transparency.

The X-rays emitted from the X-ray generator 300 can be emitted to a subject 200. The subject 200 can be a person, an object, etc.

Because the X-rays have short wavelengths, they can easily penetrate the subject 200.

The transmission amount of X-rays is determined depending on a density inside the subject 200.

By detecting the amount of X-rays transmitted through the subject 200, the internal structure of the subject 200 can be observed.

Before-penetration X-rays Xray_BP before reaching the subject 200 can reach the subject 200.

Here, X-rays that reach the subject 200 can pass through the subject 200.

The amount of X-rays transmitted through the subject 200 can vary depending on the density inside the subject 200.

After-penetration X-rays Xray_AP after penetrating the subject 200 can be incident on the digital X-ray detector 100 after passing through the subject 200.

The digital X-ray detector 100 can sense the after-penetration X-rays Xray_AP.

The digital X-ray detector 100 can sense the transmission amount of the after-penetration X-rays Xray_AP.

An X-ray image of the subject 200 can be obtained through the transmission amount of the after-penetration X-rays Xray_AP.

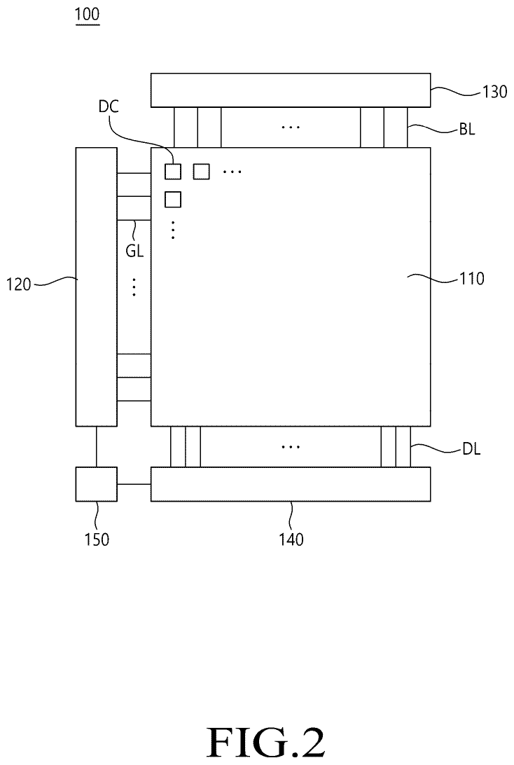

FIG. 2 is a configuration diagram of the digital X-ray detector 100 according to an embodiment of the present disclosure.

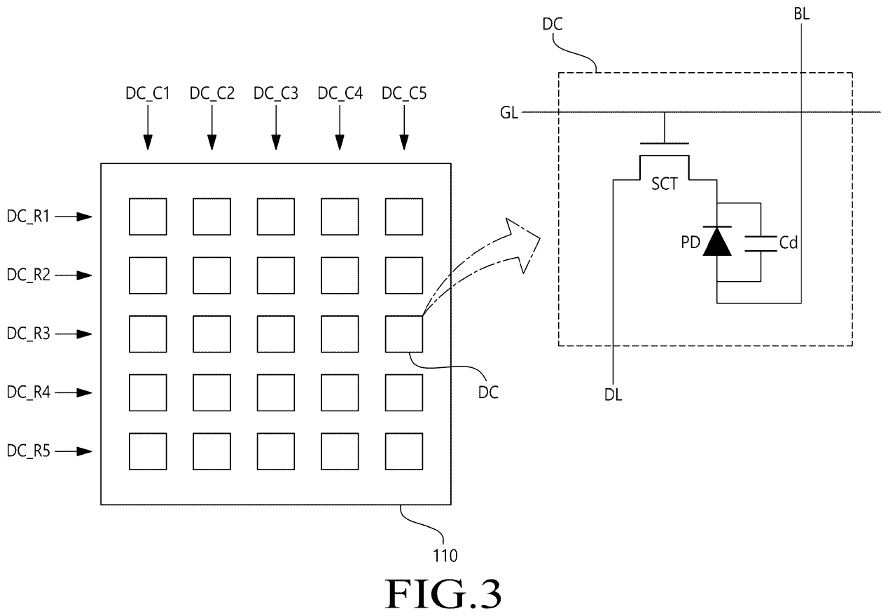

FIG. 3 is a diagram of a detection circuit DC according to the embodiment of the present disclosure.

Referring to FIG. 2, the digital X-ray detector 100 can include a digital X-ray detection panel 110, a gate driving circuit 120, a bias driving circuit 130, a readout detection circuit 140, and a controller 150.

The digital X-ray detection panel 110 can include a plurality of detection circuits DC.

The plurality of detection circuits DC can be defined by a plurality of gate lines GL, a plurality of bias lines BL and a plurality of data lines DL.

The plurality of detection circuits DC can sense X-rays. The plurality of detection circuits DC can be disposed in a matrix form.

Referring to FIG. 3, for the sake of convenience in explanation, it is illustrated that the number of the plurality of detection circuits DC is 25. The plurality of detection circuits DC are disposed in a 5*5 matrix form.

The plurality of detection circuits DC can be referred to as “column detection circuits DC_C1, DC_C2, DC_C3, DC_C4 and DC_C5” on the basis of a column direction. The plurality of detection circuits DC can be referred to as “row detection circuits DC_R1, DC_R2, DC_R3, DC_R4 and DC_R5” on the basis of a row direction. For example, detection circuits DC disposed in a first column can be first column detection circuits DC_C1, and detection circuits DC disposed in a second column can be second column detection circuits DC_C2. Detection circuits DC disposed in a first row can be first row detection circuits DC_R1, and detection circuits DC disposed in a second row can be second row detection circuits DC_R2.

Referring to FIG. 2, the gate driving circuit 120 can be electrically connected to the digital X-ray detection panel 110 through the plurality of gate lines GL.

The gate driving circuit 120 can supply a scan signal to the digital X-ray detection panel 110 through the plurality of gate lines GL.

The plurality of gate lines GL can be disposed to extend in the row direction. However, the gate driving circuit 120 and the plurality of gate lines GL can be disposed to extend in the column direction.

A first row gate line GL can be electrically connected to the first row detection circuits DC.

A second row gate line GL can be electrically connected to the second row detection circuits DC.

An nth row gate line GL can be electrically connected to nth row detection circuits DC, where n is a positive number.

The gate driving circuit 120 can supply the scan signal to the plurality of gate lines GL in row order.

The scan signal can be in a turn-off level state or a turn-on level state.

For example, after supplying the turn-on scan signal to the first row gate line GL, the turn-on scan signal can be supplied to the second row gate line GL. After supplying the turn-on scan signal to the second row gate line GL, the turn-on scan signal can be supplied to a third row gate line GL.

When the turn-on scan signal is supplied to the first row gate line GL, the turn-off scan signal can be supplied to the second row gate line GL. When the turn-on scan signal is supplied to the second row gate line GL, the turn-off scan signal can be supplied to the third row gate line GL.

Unlike this, while the turn-on scan signal is supplied to the first row gate line GL, the turn-on scan signal can also be supplied to the second row gate line GL. This can be referred to as overlap driving. While the turn-on scan signal is supplied to the second row gate line GL, the turn-on scan signal can also be supplied to the third row gate line GL. This can be referred to as overlap driving.

The bias driving circuit 130 can be electrically connected to the digital X-ray detection panel 110 through the plurality of bias lines BL.

The bias driving circuit 130 can supply a bias voltage to the digital X-ray detection panel 110 through the plurality of bias lines BL.

The plurality of bias lines BL can be disposed to extend in the column direction. However, the bias driving circuit 130 and the plurality of bias lines BL can be disposed to extend in the row direction.

A first column bias line BL can be electrically connected to the first column detection circuits DC.

A second column bias line BL can be electrically connected to the second column detection circuits DC.

An mth column bias line BL can be electrically connected to mth column detection circuits DC, where m is a positive number.

The readout detection circuit 140 can be electrically connected to the digital X-ray detection panel 110 through the plurality of data lines DL.

The readout detection circuit 140 can be supplied with detection signals from the digital X-ray detection panel 110 through the plurality of data lines DL.

The plurality of data lines DL can be disposed to extend in the column direction. However, the readout detection circuit 140 and the plurality of data lines DL can be disposed to extend in the row direction.

A first column data line DL can be electrically connected to the first column detection circuits DC.

A second column data line DL can be electrically connected to the second column detection circuits DC.

The mth column data line DL can be electrically connected to the mth column detection circuits DC.

Referring to FIG. 3, the detection circuit DC can include a detection capacitor Cd. Signals stored in a plurality of detection capacitors Cd can be supplied to the readout detection circuit 140 through the plurality of data lines DL.

Referring to FIG. 2, the controller 150 can control the gate driving circuit 120, the bias driving circuit 130, the readout detection circuit 140, and so forth.

The controller 150 can supply a start signal and a clock signal for controlling the driving timing of the gate driving circuit 120 to the gate driving circuit 120.

The controller 150 can supply a readout control signal and a readout clock signal for controlling the driving timing of the readout detection circuit 140 to the readout detection circuit 140.

Referring to FIG. 3, the detection circuit DC can include a scan transistor SCT and a pin diode PD.

The scan transistor SCT can be electrically connected between a data line DL and the pin diode PD.

The gate node of the scan transistor SCT can be electrically connected to a gate line GL.

The pin diode PD can include an anode electrode, a cathode electrode and a photoconductive layer PIN.

The cathode electrode of the pin diode PD can be electrically connected to the scan transistor SCT. The cathode electrode can be a first electrode PE1.

The anode electrode of the pin diode PD can be electrically connected to a bias line BL. The anode electrode can be a second electrode PE2.

The photoconductive layer PIN can include an N-type silicon layer, an intrinsic silicon layer and a P-type silicon layer.

The before-penetration X-rays Xray_BP can become the after-penetration X-rays Xray_AP after penetrating the subject 200.

The after-penetration X-rays Xray_AP can be converted into visible light by a scintillator.

The pin diode PD can generate electron-hole pairs in response to visible light.

A bias signal can be supplied to the second electrode PE2, and electrons of electron-hole pairs can move to the first electrode PE1 by the bias signal. A sensing signal can be generated on the basis of the amount of moved electrons.

The sensing signal can be supplied to the readout detection circuit 140.

The readout detection circuit 140 can supply transmittance data of the after-penetration X-rays Xray_AP to the controller 150 on the basis of the sensing signal.

The controller 150 can determine the transmittance of X-rays on the basis of the transmittance data of the X-rays.

Hereinafter, a plan view and a cross-sectional view of one detection circuit DC disposed in the digital X-ray detection panel 110 will be described.

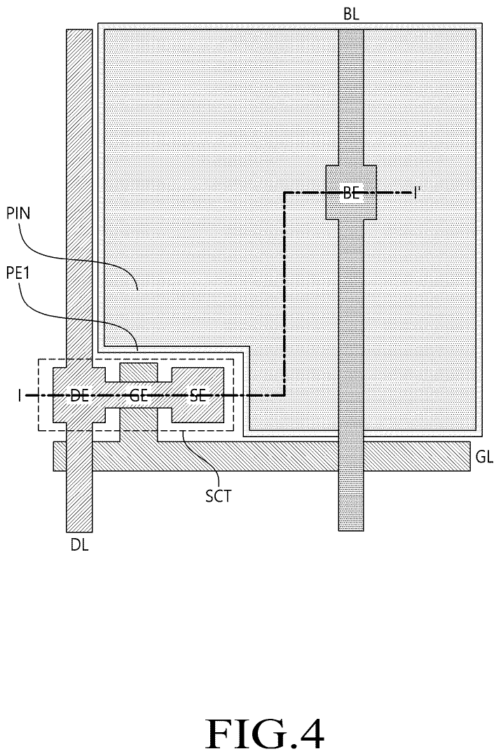

FIG. 4 is a plan view of a detection circuit disposed in the digital X-ray detection panel 110 according to an embodiment of the present disclosure.

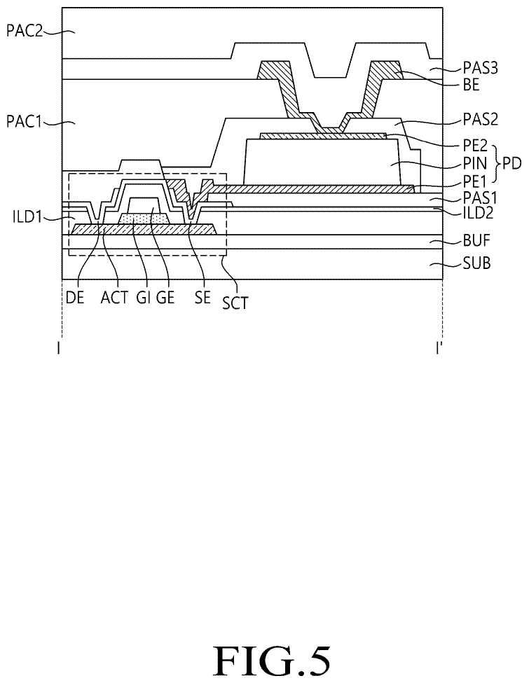

FIG. 5 is a cross-sectional view of the detection circuit disposed in the digital X-ray detection panel 110 according to the embodiment of the present disclosure, particularly, along line I-I′ of FIG. 4.

Referring to FIG. 4, a data line DL, a gate line GL, a bias line BL, a scan transistor SCT, a first electrode PE1 of a pin diode PD and a photoconductive layer PIN of the pin diode PD can be seen.

The scan transistor SCT can include a gate electrode GE, a drain electrode DE and a source electrode SE.

The scan transistor SCT can be disposed at a left lower end when viewed on the basis of the pin diode PD.

The data line DL can be electrically connected to the drain electrode DE of the scan transistor SCT.

The data line DL can be disposed on the left side of the pin diode PD. The data line DL can be disposed to extend in a vertical direction.

The gate line GL can be electrically connected to the gate electrode GE of the scan transistor SCT.

The gate line GL can be disposed at the lower end of the pin diode PD. The gate line GL can be disposed to extend in a horizontal direction. However, depending on a design, the gate line GL can be disposed in the vertical direction.

The first electrode PE1 of the pin diode PD can be electrically connected to the source electrode SE of the scan transistor SCT.

The photoconductive layer PIN of the pin diode PD can be disposed on the first electrode PE1 of the pin diode PD.

A bias electrode BE can be disposed over the photoconductive layer PIN of the pin diode PD.

The bias line BL can be electrically connected to the bias electrode BE. Alternatively, the bias line BL can be formed integrally with the bias electrode BE.

The bias line BL can be disposed on the left side of the pin diode PD. The bias line BL can be disposed to extend in the vertical direction.

Referring to the plan view shown in FIG. 4, an area of line I-I′ can be seen in FIG. 5. Hereinbelow, the cross-sectional view of the area of line I-I′ in FIG. 5 will be described.

With reference to FIG. 5, the structure of the digital X-ray detection panel 110 will be described in more detail.

A substrate SUB can be disposed at the bottom of the digital X-ray detection panel 110.

A buffer layer BUF can be disposed on the substrate SUB. The buffer layer BUF can be a layer for electrical insulation.

An active layer ACT can be disposed on the buffer layer BUF. The active layer ACT can be disposed in contact with the source electrode SE and the drain electrode DE.

A gate insulating layer GI can be disposed on the active layer ACT. The gate insulating layer GI can be a layer for electrical insulation.

The gate electrode GE can be disposed on the gate insulating layer GI. The gate electrode GE can be electrically connected to the gate line GL.

A first interlayer insulating layer ILD1 can be deposited on an entire surface to cover the active layer ACT, the gate insulating layer GI and the gate electrode GE.

A second interlayer insulating layer ILD2 can be disposed on the first interlayer insulating layer ILD1.

After the first interlayer insulating layer ILD1 and the second interlayer insulating layer ILD2 are deposited on entire surfaces, some areas of the first interlayer insulating layer ILD1 and the second interlayer insulating layer ILD2 can be removed by being etched. The first interlayer insulating layer ILD1 and the second interlayer insulating layer ILD2 can include contact holes, and the source electrode SE and the drain electrode DE can be disposed in the contact holes.

A first passivation layer PAS1 can be disposed on the second interlayer insulating layer ILD2. After the first passivation layer PAS1 is deposited on an entire surface, a contact hole can be formed in a portion of the first passivation layer PAS1 corresponding to the source electrode SE.

After a process in which the first passivation layer PAS1 is formed proceeds, the pin diode PD can be formed.

The pin diode PD can include the first electrode PE1, the photoconductive layer PIN and a second electrode PE2.

The first electrode PE1 can be disposed on the first passivation layer PAS1. The first electrode PE1 can be electrically connected to the source electrode SE. The first electrode PE1 can be disposed in contact with the source electrode SE. The first electrode PE1 can be a cathode electrode.

The photoconductive layer PIN can be disposed on the first electrode PE1. The photoconductive layer PIN can include an N-type silicon layer, an intrinsic silicon layer and a P-type silicon layer.

The second electrode PE2 can be disposed on the photoconductive layer PIN. The second electrode PE2 can be an anode electrode.

The height of the photoconductive layer PIN can be higher than the first electrode PE1 and the second electrode PE2.

A second passivation layer PAS2 can be disposed to cover the pin diode PD. After the second passivation layer PAS2 is deposited, a contact hole can be formed in the second passivation layer PAS2.

A first protective layer PAC1 can be disposed on the second passivation layer PAS2. The first protective layer PAC1 can be a planarization layer. After the first protective layer PAC1 is deposited on an entire surface, a contact hole can be formed in a partial area of the first protective layer PAC1.

The bias electrode BE can be disposed on the first protective layer PAC1. The bias electrode BE can be electrically connected to the second electrode PE2 of the pin diode PD through the contact hole of the second passivation layer PAS2.

A third passivation layer PAS3 can be disposed to cover the first protective layer PAC1 and the bias electrode BE. The third passivation layer PAS3 can be a layer for insulating the bias electrode BE from other layers.

A second protective layer PAC2 can be disposed to cover the third passivation layer PAS3. The second protective layer PAC2 can be a planarization layer.

The wider the area of the photoconductive layer PIN is, the more a sensing rate for X-rays can increase. Hereinafter, a structure in which the area of the photoconductive layer PIN can be further widened will be described.

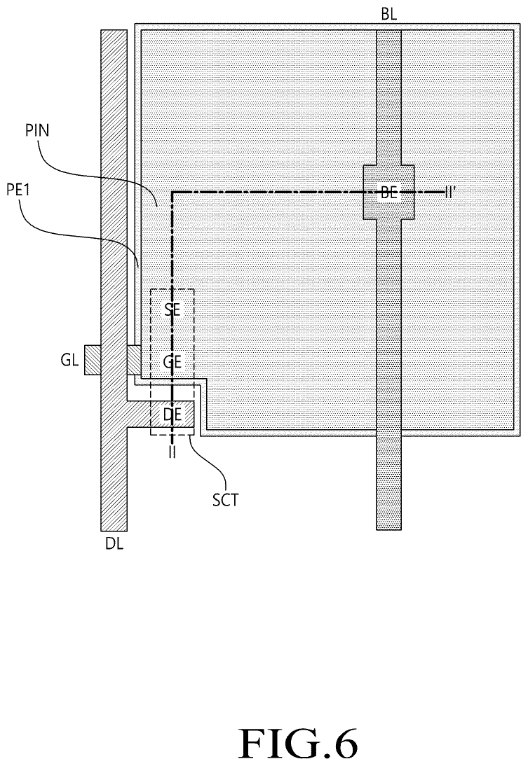

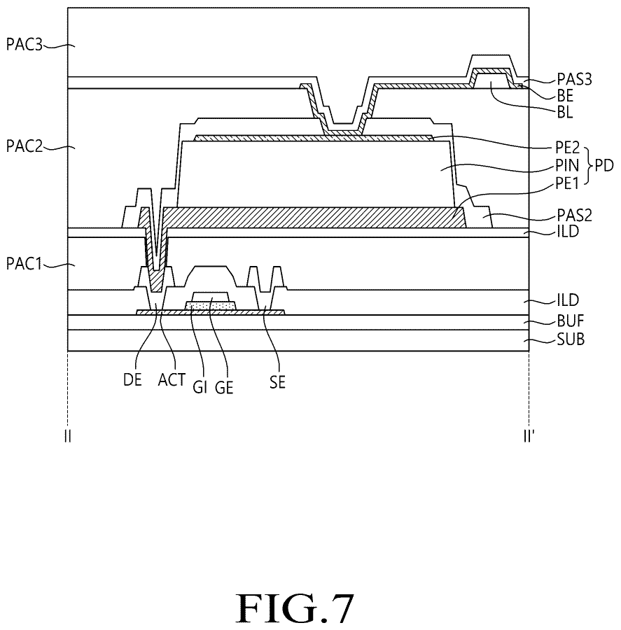

Referring to FIGS. 4 and 6, it can be seen that the area of a photoconductive layer PIN shown in FIG. 6 is wider than the area of the photoconductive layer PIN shown in FIG. 4. Detailed description will be made hereunder with reference to FIGS. 6 and 7.

Particularly, FIG. 6 is a plan view of a detection circuit disposed in the digital X-ray detection panel 110 according to an embodiment of the present disclosure.

Further, FIG. 7 is a cross-sectional view of the detection circuit disposed in the digital X-ray detection panel 110 according to the embodiment of the present disclosure, particularly along line II-II′ of FIG. 6.

The digital X-ray detection panel 110 shown in FIGS. 6 and 7 is another embodiment different from the digital X-ray detection panel 110 shown in FIGS. 4 and 5.

Referring to FIG. 6, a gate electrode GE and a source electrode SE can be disposed below a first electrode PE1 of a pin diode PD. As the gate electrode GE and the source electrode SE are disposed below the first electrode PE1, the area of the photoconductive layer PIN of the pin diode PD can be further widened.

A scan transistor SCT can be disposed at the left lower end of the pin diode PD.

The source electrode SE and a drain electrode DE of the scan transistor SCT can be disposed in a vertical direction.

The source electrode SE of the scan transistor SCT can be disposed to overlap with the first electrode PE1 of the pin diode PD.

The drain electrode DE of the scan transistor SCT may not overlap with the first electrode PE1 of the pin diode PD.

Referring to FIG. 7, it can be seen that the scan transistor SCT is disposed below the pin diode PD.

The scan transistor SCT can be disposed on a substrate SUB and a buffer layer BUF.

The scan transistor SCT can include an active layer ACT, a gate insulating layer GI, the gate electrode GE, the source electrode SE, the drain electrode DE and an interlayer insulating layer ILD.

A first protective layer PAC1 can be disposed to cover the scan transistor SCT. The first protective layer PAC1 can include a contact hole.

An interlayer insulating layer ILD can be disposed on the first protective layer PAC1. The interlayer insulating layer ILD can include a contact hole.

The pin diode PD can be disposed on the interlayer insulating layer ILD.

The pin diode PD can include the first electrode PE1, the photoconductive layer PIN and a second electrode PE2.

The first electrode PE1 can be disposed on the interlayer insulating layer ILD. The first electrode PE1 can be electrically connected to the drain electrode DE through the contact hole of the interlayer insulating layer ILD and the contact hole of the first protective layer PAC1.

The photoconductive layer PIN can be disposed on the first electrode PE1.

The second electrode PE2 can be disposed on the photoconductive layer PIN.

A second passivation layer PAS2 can be disposed to cover the second electrode PE2, the photoconductive layer PIN and the first electrode PE1.

Since the scan transistor SCT is disposed below the pin diode PD, a portion of the scan transistor SCT can be disposed to overlap with the pin diode PD.

The gate electrode GE can be disposed to overlap with the first electrode PE1, the photoconductive layer PIN and the second electrode PE2.

The gate insulating layer GI can be disposed to overlap with the first electrode PE1, the photoconductive layer PIN and the second electrode PE2.

The source electrode SE can be disposed to overlap with the first electrode PE1, the photoconductive layer PIN and the second electrode PE2.

The active layer ACT can be disposed to overlap with the first electrode PE1, the photoconductive layer PIN and the second electrode PE2.

The active layer ACT can be composed of any one of amorphous silicon, low temperature polysilicon and oxide. Amorphous silicon can be referred to as a-Si (amorphous silicon). Low temperature polysilicon can be referred to as LTPS (low temperature polysilicon). Oxide can be referred to as oxide.

When the active layer ACT is a low temperature polysilicon active layer including low temperature polysilicon, a transistor which includes the corresponding active layer ACT can be referred to as an LTPS semiconductor or an LTPS TFT. While amorphous silicon has a relatively disordered arrangement of silicon, low temperature polysilicon has a uniformly arranged crystalline silicon. As crystals are arranged relatively uniformly, the moving speed of electrons in low temperature polysilicon can be about 100 times faster than the moving speed of electrons in amorphous silicon.

When the active layer ACT is an oxide active layer including oxide, a transistor which includes the corresponding active layer ACT can be referred to as an oxide semiconductor or an oxide TFT. For example, the active layer ACT included in the oxide semiconductor can include at least one of IGZO (InGaZnO)-based, IGZTO (InGaZnSnO)-based, IZO (InZnO)-based, IGO (InGaO)-based, ITO (InSnO)-based, ITZO (InSnZnO)-based, InO (InO)-based, ZnO (ZnO)-based and FIZO (FeInZnO)-based oxide semiconductor materials. However, the embodiment of the present disclosure is not limited thereto, and the active layer ACT can be made of other oxide semiconductor materials known in the art.

A second protective layer PAC2 can be disposed to cover the second passivation layer PAS2. The second protective layer PAC2 can include a contact hole. The second protective layer PAC2 can be a layer for planarization.

A third passivation layer PAS3 can be disposed to cover the second protective layer PAC2. The third passivation layer PAS3 can be a layer for insulating a bias electrode BE from other layers.

A third protective layer PAC3 can be disposed on the third passivation layer PAS3. The third protective layer PAC3 can be a layer for planarization.

The scan transistor SCT and the pin diode PD disposed in each of FIGS. 4 and 6 are disposed at different layers from each other. Unlike the scan transistor SCT disposed in each of FIGS. 4 and 6, when a transistor is disposed on the side surface of the pin diode PD, the area of the photoconductive layer PIN can be further widened.

The drain electrode DE of the scan transistor SCT can be electrically connected to the first electrode PE1 through the contact hole in the first protective layer PAC1. Since the first protective layer PAC1 includes the contact hole, the first protective layer PAC1 can be formed to be somewhat uneven. In particular, when the pin diode PD is disposed to overlap with the scan transistor SCT, the pin diode PD can be disposed over the first protective layer PAC1 which is not even. In this case, the first electrode PE1, the photoconductive layer PIN and the second electrode PE2 included in the pin diode PD can also be disposed unevenly, and the reliability of the pin diode PD can decrease.

The active layer ACT of the scan transistor SCT can include oxide, and in this case, the active layer ACT can be an oxide active layer.

Referring to FIG. 7, after the scan transistor SCT is disposed, the pin diode PD can be disposed to overlap with the scan transistor SCT. In particular, as the contact hole of the first protective layer PAC1 is disposed below the pin diode PD, the upper end of the contact hole of the first protective layer PAC1 can be disposed to be covered by the bottom of the pin diode PD. The first protective layer PAC1 can include a silicon nitride layer (SiNx). The first protective layer PAC1 can emit hydrogen gas due to the silicon nitride layer (SiNx). As the upper end of the contact hole of the first protective layer PAC1 is disposed to be covered by the bottom of the pin diode PD, hydrogen gas may not be discharged to the outside and can be introduced into the oxide active layer. When hydrogen gas is introduced into the oxide active layer, a problem can arise in that the characteristics of the oxide active layer change.

That is to say, in the case where the scan transistor SCT is disposed below the pin diode PD, a problem can arise in the reliability of the pin diode PD. In addition, a problem can arise in that hydrogen gas is not discharged to the outside and is introduced into the oxide active layer.

Hereinafter, the digital X-ray detector 100 which improves the reliability of the pin diode PD and does not change the characteristics of a transistor due to a pin diode (PD) process will be described.

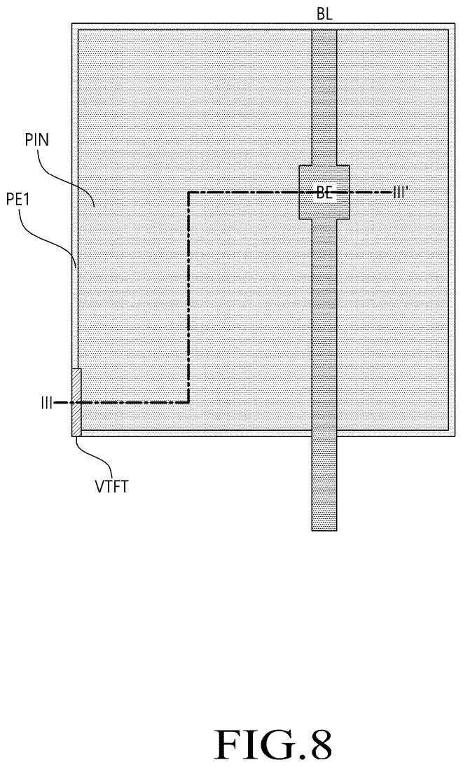

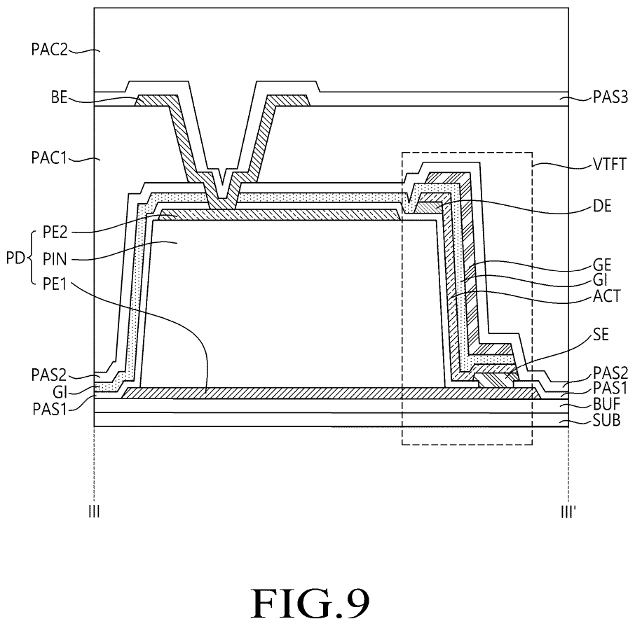

Referring to FIGS. 8 and 9, a structure in which a transistor is disposed on the side surface of a pin diode PD will be described.

Particularly, FIG. 8 is a plan view of the digital X-ray detection panel 110 according to an embodiment of the present disclosure.

Further, FIG. 9 is a cross-sectional view of the digital X-ray detection panel 110 according to the embodiment of the present disclosure, along line III-III′ of FIG. 8.

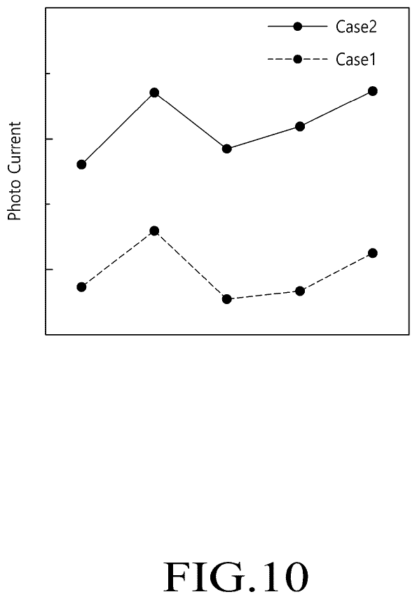

FIG. 10 shows experimental data on photo current according to the embodiment of the present disclosure.

Referring to FIGS. 8 and 9, the digital X-ray detection panel 110 can include a pin diode PD and a vertical transistor VTFT.

The pin diode PD can include a first electrode PE1, a second electrode PE2 disposed over the first electrode PE1, and a photoconductive layer PIN disposed between the first electrode PE1 and the second electrode PE2.

The vertical transistor VTFT can be disposed on the side surface of the photoconductive layer PIN, and can be disposed to overlap with the first electrode PE1.

The vertical transistor VTFT can perform the same function as the scan transistor SCT shown in FIG. 3.

The vertical transistor VTFT can be disposed to overlap with a portion of the photoconductive layer PIN.

The vertical transistor VTFT can be disposed to overlap with the first electrode PE1.

Since the vertical transistor VTFT is disposed on the side surface of the photoconductive layer PIN, an area occupied by the photoconductive layer PIN in the detection circuit DC can be further widened. The area of the first electrode PE1 can also be widened.

When viewed on the basis of the plan view shown in FIG. 8, the vertical transistor VTFT can be disposed at the left lower end of the first electrode PE1. However, the vertical transistor VTFT can be disposed on the side surface of the photoconductive layer PIN in an area other than the left lower end.

Referring to FIG. 9, the vertical transistor VTFT can include a source electrode SE disposed in contact with the first electrode PE1, an active layer ACT disposed to overlap with the source electrode SE, a gate electrode GE disposed on the side surface of the active layer ACT, and a drain electrode DE disposed in contact with the active layer ACT.

An area of line III-III′ can be seen in the plan view of FIG. 8. Referring to FIG. 9, the cross-sectional view of the area of line III-III′ of FIG. 8 can be seen. The cross-sectional view of the area III-III′ will be described hereunder.

A substrate SUB can be disposed at the bottom of the digital X-ray detection panel 110. Referring to FIG. 9, when viewed on the basis of the cross-sectional view of the digital X-ray detection panel 110, the substrate SUB can have a rectangular shape.

A buffer layer BUF can be disposed on the substrate SUB. The buffer layer BUF can be a layer for insulation. Referring to FIG. 9, when viewed on the basis of the cross-sectional view of the digital X-ray detection panel 110, the buffer layer BUF can have a rectangular shape.

The first electrode PE1 can be disposed on the buffer layer BUF. The first electrode PE1 can be disposed in contact with the photoconductive layer PIN and the source electrode SE. Referring to FIG. 9, when viewed on the basis of the cross-sectional view of the digital X-ray detection panel 110, the first electrode PE1 can have a rectangular shape. Referring to FIG. 9, a first passivation layer PAS1 can be disposed on the left and right areas of the first electrode PE1. Since a second passivation layer PAS2 can be disposed on the first passivation layer PAS1, the second passivation layer PAS2 can be disposed on the left and right areas of the first electrode PE1.

The photoconductive layer PIN can be disposed to overlap with the first electrode PE1. The photoconductive layer PIN can be electrically connected between the first electrode PE1 and the second electrode PE2. Referring to FIG. 9, the width of the photoconductive layer PIN can be narrower than the width of the first electrode PE1. When viewed on the basis of the cross-sectional view shown in FIG. 9, the photoconductive layer PIN can have a trapezoidal shape or a quadrangular shape.

Referring to FIG. 9, the active layer ACT can be disposed on the right side surface of the photoconductive layer PIN. The active layer ACT can be disposed on the right upper portion of the photoconductive layer PIN. The active layer ACT can be disposed on the right lower portion of the photoconductive layer PIN. In other words, the active layer ACT can be disposed in the areas of the right upper portion, the right side surface and the right lower portion of the photoconductive layer PIN.

The gate electrode GE can be disposed on the right side of the photoconductive layer PIN. The source electrode SE can be disposed on the right lower portion of the photoconductive layer PIN. The drain electrode DE can be disposed on the right upper portion of the photoconductive layer PIN.

The thickness of the photoconductive layer PIN can be thicker than the first electrode PE1 and the second electrode PE2. Since the active layer ACT is disposed on the side surface of the photoconductive layer PIN, if the thickness of the photoconductive layer PIN increases, the length of the active layer ACT can also increase. Conversely, if the thickness of the photoconductive layer PIN decreases, the length of the active layer ACT can also decrease. In addition, depending on the thickness of the photoconductive layer PIN, the length of the gate electrode GE can increase or decrease.

The second electrode PE2 can be disposed on the photoconductive layer PIN. Referring to FIG. 9, the width of the second electrode PE2 can be narrower than the width of the photoconductive layer PIN.

The active layer ACT can be disposed on the right side of the second electrode PE2. The second electrode PE2 can be disposed on the same plane as at least a portion of the active layer ACT which is vertically disposed. When viewed on the basis of the cross-sectional view shown in FIG. 9, the active layer ACT can be disposed to extend in a vertical direction. A portion of the active layer ACT which is disposed to extend in the vertical direction can be disposed on the same plane as the second electrode PE2.

The gate electrode GE can be disposed on the right side of the second electrode PE2. The second electrode PE2 can be disposed on the same plane as at least a portion of the gate electrode GE which is vertically disposed. When viewed on the basis of the cross-sectional view shown in FIG. 9, the gate electrode GE can be disposed to extend in the vertical direction. A portion of the gate electrode GE which is disposed to extend in the vertical direction can be disposed on the same plane as the second electrode PE2.

The second electrode PE2 can be disposed in contact with a bias electrode BE on the upper surface of the second electrode PE2. The second electrode PE2 can be disposed in contact with the photoconductive layer PIN on the lower surface thereof.

The first passivation layer PAS1 can be disposed to cover the second electrode PE2, the photoconductive layer PIN, the first electrode PE1 and the buffer layer BUF. The first passivation layer PAS1 can be a layer for insulation. After the first passivation layer PAS1 is disposed, the source electrode SE and the drain electrode DE can be disposed on the first passivation layer PAS1.

After the first passivation layer PAS1 is deposited on an entire surface, portions of the first passivation layer PAS1 can be removed by being etched. Accordingly, the first passivation layer PAS1 can include contact holes. The first passivation layer PAS1 can include a first contact hole in an area which overlaps only with the first electrode PE1 among the first electrode PE1, the photoconductive layer PIN and the second electrode PE2. In addition, the first passivation layer PAS1 can include a second contact hole in an area which is disposed to overlap with all of the first electrode PE1, the photoconductive layer PIN and the second electrode PE2.

The source electrode SE can be disposed in the first contact hole of the first passivation layer PAS1. The source electrode SE can be electrically connected to the first electrode PE1.

The source electrode SE can be disposed in contact with the first electrode PE1.

The source electrode SE can be disposed in contact with the active layer ACT. The source electrode SE can be disposed to overlap with the gate electrode GE, the active layer ACT and the first electrode PE1.

The drain electrode DE can be disposed on the first passivation layer PAS1. Referring to FIG. 9, the drain electrode DE can be disposed in an area which overlaps with the photoconductive layer PIN and the second electrode PE2. Namely, the drain electrode DE can be disposed in an area which does not overlap with the first electrode PE1 but overlaps with the photoconductive layer PIN and the second electrode PE2.

The drain electrode DE can be disposed in contact with the active layer ACT. The upper portion of the drain electrode DE and the right portion of the drain electrode DE can be disposed in contact with the active layer ACT.

The right end portion of the drain electrode DE can be disposed to overlap with the gate electrode GE, the active layer ACT, the first passivation layer PAS1 and the first electrode PE1.

The drain electrode DE can be located higher than the source electrode SE.

The active layer ACT can be disposed to cover the drain electrode DE, the first passivation layer PAS1 and the source electrode SE. The active layer ACT can include a horizontally disposed portion and a vertically disposed portion. Referring to FIG. 9, the vertically disposed portion of the active layer ACT can have a predetermined slope.

The active layer ACT can include a first horizontal portion which is disposed on the drain electrode DE, a second horizontal portion which is disposed on the source electrode SE, and a vertical portion as a portion between the first horizontal portion and the second horizontal portion. That is to say, referring to FIG. 9, the active layer ACT can be disposed in a shape which extends from the left upper end to the right upper end, extends downward in the vertical direction and then extends rightward again.

The first horizontal portion of the active layer ACT can be disposed to overlap with the gate electrode GE, the drain electrode DE and the first electrode PE1. In addition, the first horizontal portion of the active layer ACT can be disposed to overlap with the photoconductive layer PIN, the first passivation layer PAS1 and the second passivation layer PAS2.

The second horizontal portion of the active layer ACT can be disposed to overlap with the gate electrode GE, the source electrode SE and the first electrode PE1. The second horizontal portion of the active layer ACT can be disposed to overlap with the first passivation layer PAS1 and the second passivation layer PAS2.

The vertical portion of the active layer ACT can be disposed to overlap with the gate electrode GE and the photoconductive layer PIN. The photoconductive layer PIN can be disposed on the left side of the vertical portion of the active layer ACT. The gate electrode GE can be disposed on the right side of the vertical portion of the active layer ACT. Since the vertical portion of the active layer ACT is disposed on the right side surface of the photoconductive layer PIN, the length of the vertical portion of the active layer ACT can increase or decrease depending on the thickness of the photoconductive layer PIN.

When the active layer ACT is exposed to external light, the threshold voltage of the vertical transistor VTFT can shift.

The active layer ACT can be disposed to overlap with the first electrode PE1.

The first electrode PE1 can include a metal constituent. Therefore, the first electrode PE1 can reflect external light. In other words, the first electrode PE1 can perform a light blocking function.

The left-right width and top-bottom width of the active layer ACT can be shorter than the left-right width and top-bottom width of the first electrode PE1. For example, when viewed on the basis of the cross-sectional view of FIG. 9, the left-right width of the active layer ACT in a planar direction can be narrower than the left-right width of the first electrode PE1 in the planar direction. Referring to FIG. 9, the active layer ACT can be disposed in the vertical direction. The entire portion of the active layer ACT disposed in the vertical direction can be disposed to overlap with the first electrode PE1.

Referring to FIG. 8, the horizontal area of the vertical transistor VTFT can be narrower than the horizontal area of the first electrode PE1. Referring to FIG. 8, an area where the vertical transistor VTFT is disposed can be included within an area where the first electrode PE1 is disposed. That is to say, all components of the vertical transistor VTFT can be disposed on the first electrode PE1.

The active layer ACT can be disposed on the side surface of the photoconductive layer PIN to overlap with the upper surface of the first electrode PE1 which includes an opaque metal.

For example, the first electrode PE1 can be made of an opaque conductive material, for example, copper (Cu), aluminum (Al), molybdenum (Mo), nickel (Ni), titanium (Ti), chromium (Cr) or an alloy thereof, but is not limited thereto.

All the components of the vertical transistor VTFT can be disposed on the first electrode PE1, and the active layer ACT of the vertical transistor VTFT can also be disposed on the first electrode PE1. Since the active layer ACT is disposed on the first electrode PE1, the first electrode PE1 can block external light incident on the active layer ACT. Since the first electrode PE1 is an opaque material, the first electrode PE1 may not transmit light. In addition, the first electrode PE1 can reflect external light to prevent external light from being incident on the active layer ACT. In other words, the first electrode PE1 can protect the active layer ACT from external light.

Referring to FIG. 8, the vertical transistor VTFT can be disposed to overlap with a portion of the first electrode PE1. Namely, the active layer ACT of the vertical transistor VTFT can be disposed to overlap with a portion of the first electrode PE1.

Referring to FIG. 9, the vertical transistor VTFT can be disposed to overlap with a portion of the first electrode PE1. Namely, the active layer ACT of the vertical transistor VTFT can be disposed to overlap with a portion of the first electrode PE1. As the active layer ACT is protected from external light by the first electrode PE1, the threshold voltage of the vertical transistor VTFT may not be changed by external light.

A gate insulating layer GI can be disposed to cover the first passivation layer PAS1, the drain electrode DE and the active layer ACT. The gate insulating layer GI can be a layer for insulating the gate electrode GE from other layers. Since the gate insulating layer GI is disposed around the pin diode PD, the gate insulating layer GI can be disposed in a shape which covers the pin diode PD. That is to say, the gate insulating layer GI can have a shape which covers the pin diode PD and in which a central portion protrudes upward.

The gate electrode GE can be disposed in contact with the gate insulating layer GI. The gate electrode GE can include a first horizontal portion, a vertical portion and a second horizontal portion. The first horizontal portion can be disposed relatively at a left upper end, and the second horizontal portion can be disposed relatively at a right lower end. The first horizontal portion can be located higher than the second horizontal portion. The vertical portion can be a portion between the first horizontal portion and the second horizontal portion.

The first horizontal portion of the gate electrode GE can be disposed on the first horizontal portion of the active layer ACT. The first horizontal portion of the gate electrode GE can be disposed to overlap with the active layer ACT, the drain electrode DE and the first electrode PE1. The first horizontal portion of the gate electrode GE can be disposed to overlap with the photoconductive layer PIN.

The vertical portion of the gate electrode GE can be disposed between the gate insulating layer GI and the second passivation layer PAS2. The vertical portion of the gate electrode GE can be disposed in the vertical direction like the vertical portion of the active layer ACT. The gate insulating layer GI and the active layer ACT can be disposed in the left side area of the vertical portion of the gate electrode GE. The drain electrode DE can be disposed at the left upper end of the vertical portion of the gate electrode GE. The vertical portion of the gate electrode GE can be disposed to overlap with also the source electrode SE.

The second horizontal portion of the gate electrode GE can be disposed to overlap with the active layer ACT and the source electrode SE. The upper portion of the second horizontal portion of the gate electrode GE can be disposed in contact with the second passivation layer PAS2. The lower portion of the second horizontal portion of the gate electrode GE can be disposed in contact with the gate insulating layer GI. The photoconductive layer PIN can be disposed on the left side of the second horizontal portion of the gate electrode GE.

The second passivation layer PAS2 can be disposed to cover the gate electrode GE, the gate insulating layer GI and the first passivation layer PAS1. The second passivation layer PAS2 can be a layer for electrical insulation. After the second passivation layer PAS2 is deposited on an entire surface, a process of forming a contact hole can proceed. The contact hole can be formed as the second passivation layer PAS2, the gate insulating layer GI and the first passivation layer PAS1 are etched, and can be formed to expose the second electrode PE2.

A first protective layer PAC1 can be disposed on the second passivation layer PAS2. The first protective layer PAC1 can be a layer for planarization. After the first protective layer PAC1 is deposited on an entire surface, a contact hole can be formed in the first protective layer PAC1.

The bias electrode BE can be disposed in the contact hole of the first protective layer PAC1. The bias electrode BE can be disposed in contact with the second electrode PE2.

The bias electrode BE can include a portion which contacts the upper surface of the first protective layer PAC1, a portion which covers the contact hole of the first protective layer PAC1, and a portion which contacts the second electrode PE2. In addition, the bias electrode BE can include a portion which contacts the second passivation layer PAS2, the gate insulating layer GI and the first passivation layer PAS1.

Since the bias electrode BE is disposed in the area of the contact hole of the first protective layer PAC1, the bias electrode BE can be disposed in a shape whose central portion is recessed.

A third passivation layer PAS3 can be disposed on the bias electrode BE. Since the third passivation layer PAS3 is disposed on the bias electrode BE, the third passivation layer PAS3 can be disposed in a shape whose central portion is recessed.

A second protective layer PAC2 can be disposed on the third passivation layer PAS3. The second protective layer PAC2 can be a layer for planarization.

Referring to FIGS. 8 and 9, the bias electrode BE can be electrically connected to a bias line BL. The gate electrode GE can be electrically connected to a gate line GL. The drain electrode DE can be electrically connected to a data line DL.

Referring to FIG. 8, the bias line BL can be disposed vertically. The gate line GL can be disposed in the same direction as the bias line BL. In other words, the gate line GL can be disposed vertically. In this case, the bias driving circuit 130 and the gate driving circuit 120 can be disposed in the same direction. However, the bias line BL can be disposed vertically, and the gate line GL can be disposed horizontally. Namely, the gate line GL which is electrically connected to the vertical transistor VTFT shown in FIG. 9 can be disposed in the vertical direction or a horizontal direction.

The bias line BL can be disposed vertically. The data line DL can be disposed in the same direction as the bias line BL. Namely, the data line DL can be disposed vertically. In this case, the bias driving circuit 130 and the readout driving circuit 140 can be disposed in the same direction.

Referring to FIG. 9, the vertical transistor VTFT can be disposed on the side surface of the pin diode PD. Since the source electrode SE, the gate electrode GE and the drain electrode DE of the vertical transistor VTFT are disposed in such a way to overlap with each other in the vertical direction, an area occupied by the vertical transistor VTFT in the horizontal direction is relatively small. Therefore, by an area by which an area occupied by the vertical transistor VTFT in the horizontal direction decreases, the pin diode PD can be disposed more widely in the horizontal direction. As the photoconductive layer PIN of the pin diode PD is disposed with a wide area, photo current can be improved.

The digital X-ray detection panel shown in FIG. 7 has an advantage that the area of the photoconductive layer is wider than that in the digital X-ray detection panel shown in FIG. 5, but a process for forming a protective layer should be added. The digital X-ray detection panel shown in FIG. 9 has an advantage that the area of the photoconductive layer is wider than that in the digital X-ray detection panel shown in FIG. 7 and the number of processes for forming protective layers decreases.

In the digital X-ray detection panels shown in FIGS. 5 and 7, the pin diode is formed after the scan transistor is formed. Therefore, in the case where the scan transistor is an oxide semiconductor, hydrogen can diffuse to the scan transistor during a process in which the pin diode is formed, and thus, the characteristics of the scan transistor can change. On the other hand, in the digital X-ray detection panel shown in FIG. 9, since the vertical transistor is formed after the pin diode is first formed, the degree of freedom in the conditions of a process for forming the pin diode can be improved.

Referring to FIG. 10, Case 1 represents experimental data in a case where a transistor is disposed in the horizontal direction, and Case 2 represents experimental data in a case where a transistor is disposed in the vertical direction. Compared to the area of the photoconductive layer PIN in Case 1, the area of the photoconductive layer PIN in Case 2 can be wider. Accordingly, the amount of photo current in Case 2 is larger than the amount of photo current in Case 1.

When the digital X-ray detector 100 includes the vertical transistor VTFT shown in FIG. 9, the amount of photo current flowing through the digital X-ray detector 100 can increase.

That is to say, the embodiments of the present disclosure can provide the digital X-ray detector 100 capable of improving photo current.

The embodiments of the present disclosure can provide the digital X-ray detector 100 with an improved area of the photoconductive layer PIN.

The embodiments of the present disclosure can provide the digital X-ray detector 100 having a structure capable of protecting a transistor from external light.

The embodiments of the present disclosure can provide the digital X-ray detector 100 capable of low power consumption as photo current is improved.

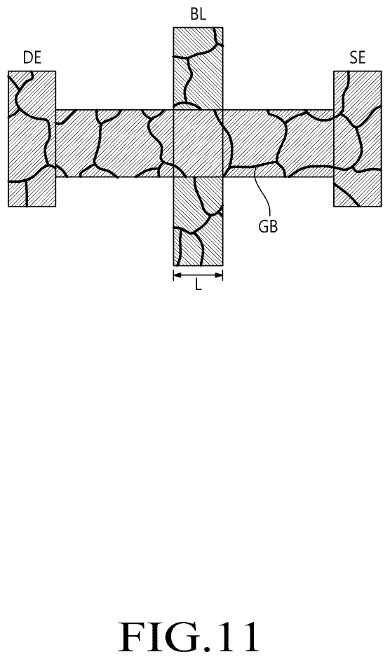

FIG. 11 is a cross-sectional view of the scan transistor VTFT according to the embodiment of the present disclosure.

Referring to FIG. 11, the vertical transistor VTFT can include the gate electrode GE, the drain electrode DE and the source electrode SE. The channel length of the active layer ACT of the vertical transistor VTFT can be equal to the length of the left-right width of the gate electrode GE.

The active layer ACT of the vertical transistor VTFT can be composed of any one of amorphous silicon, low temperature polysilicon and oxide. When the active layer ACT of the vertical transistor VTFT includes low temperature polysilicon, the vertical transistor VTFT can be referred to as an LTPS transistor or an LTPS TFT.

When the active layer ACT of the vertical transistor VTFT is low temperature polysilicon, the active layer ACT can be composed in a shape in which several single crystals gather together. Referring to FIG. 11, the active layer ACT including low temperature polysilicon can include a plurality of single crystal structures, and there are boundaries between the plurality of single crystal structures. The boundaries of the plurality of single crystal structures can be referred to as grain boundaries. When the width of a grain boundary is smaller than the channel length of the active layer ACT, a negative shift phenomenon of threshold voltage by X-rays can occur significantly. The negative shift of threshold voltage refers to a phenomenon in which the magnitude of the threshold voltage of a transistor decreases. When the width of a grain boundary is larger than the channel length of the active layer ACT or when no grain boundary exists in the active layer ACT, the negative shift phenomenon of threshold voltage by X-rays may not occur. In other words, the active layer ACT may not be damaged by X-rays.

In particular, when the channel length is 2 micrometers or less, the negative shift phenomenon of threshold voltage by X-rays can be further prevented. Since the vertical transistor VTFT is disposed on the side surface of the pin diode PD, depending on the thickness design of the pin diode PD, the length of the active layer ACT of the vertical transistor VTFT can be adjusted. When the thickness of the pin diode PD is designed to be 1 micrometer, the length of the active layer ACT of the vertical transistor VTFT can be designed to be less than 2 micrometers.

Brief description of e embodiments of the present disclosure described above is as follows.

Embodiments of the present disclosure can provide a digital X-ray detection panel including a substrate; a pin diode including a first electrode, a second electrode disposed on the first electrode, and a photoconductive layer disposed between the first electrode and the second electrode; and a vertical transistor disposed on a side surface of the photoconductive layer to overlap with the first electrode.

According to one or more aspects of the present disclosure, the vertical transistor can include a source electrode disposed in contact with the first electrode, an active layer disposed to overlap with the source electrode, a gate electrode disposed on a side surface of the active layer, and a drain electrode disposed in contact with the active layer.

According to one or more aspects of the present disclosure, a left-right width and a top-bottom width of the active layer can be shorter than a left-right width and a top-bottom width of the first electrode, and the active layer can be disposed on the side surface of the photoconductive layer to overlap with an upper surface of the first electrode including an opaque metal.

According to one or more aspects of the present disclosure, the first electrode can include any one of copper, aluminum, molybdenum, nickel, titanium and chromium, or can include an alloy of at least two of copper, aluminum, molybdenum, nickel, titanium and chromium.

According to one or more aspects of the present disclosure, the active layer can be disposed in a vertical direction in correspondence to the side surface of the photoconductive layer, the vertical transistor can further include a gate insulating layer disposed between the active layer and the gate electrode, and the gate electrode can be disposed in the vertical direction in correspondence to the side surface of the photoconductive layer.

According to one or more aspects of the present disclosure, the drain electrode can be disposed to overlap with the gate electrode, and the source electrode can be disposed to overlap with the gate electrode.

According to one or more aspects of the present disclosure, the vertical transistor can further include a first passivation layer disposed between the photoconductive layer and the active layer, and a second passivation layer disposed to cover the gate electrode.

According to one or more aspects of the present disclosure, the drain electrode can be disposed on the photoconductive layer to contact the active layer, and the source electrode can be disposed on a lower portion of the side surface of the photoconductive layer to contact the active layer.

According to one or more aspects of the present disclosure, the active layer of the vertical transistor can include low temperature polysilicon, and a width of a grain boundary of the low temperature polysilicon can be longer than a channel length of the active layer.

According to one or more aspects of the present disclosure, the digital X-ray detection panel can further include a first protective layer disposed on the second electrode, a bias electrode disposed on the first protective layer to contact the second electrode, and a second protective layer disposed on the bias electrode.

According to one or more aspects of the present disclosure, the digital X-ray detection panel can further include a plurality of detection circuits electrically connected to a plurality of gate lines, a plurality of data lines and a plurality of bias lines, and each of the plurality of detection circuits can include the pin diode and the vertical transistor. The drain electrode of the vertical transistor can be electrically connected to a data line, the source electrode of the vertical transistor can be electrically connected to the first electrode of the pin diode, and the second electrode of the pin diode can be electrically connected to a bias line.

According to one or more aspects of the present disclosure, the active layer of the vertical transistor can include oxide, and the oxide can include any one of IGZO-based, IGZTO-based, IZO-based, IGO-based, ITO-based, ITZO-based, InO-based, ZnO-based and FIZO-based oxide.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A digital X-ray detector comprising:
a substrate;
a pin diode including a first electrode, a second electrode disposed on the first electrode, and a photoconductive layer disposed between the first electrode and the second electrode; and
a vertical transistor disposed on a side surface of the photoconductive layer to overlap with the first electrode.

2. The digital X-ray detector of claim 1, wherein the vertical transistor comprises:
a source electrode disposed in contact with the first electrode;
an active layer disposed to overlap with the source electrode;
a gate electrode disposed on a side surface of the active layer; and
a drain electrode disposed in contact with the active layer.

3. The digital X-ray detector of claim 2, wherein a left-right width and a top-bottom width of the active layer are shorter than a left-right width and a top-bottom width of the first electrode, and
the active layer is disposed on the side surface of the photoconductive layer to overlap with an upper surface of the first electrode including an opaque metal.

4. The digital X-ray detector of claim 3, wherein the first electrode includes any one of copper, aluminum, molybdenum, nickel, titanium and chromium, or includes an alloy of at least two of copper, aluminum, molybdenum, nickel, titanium and chromium.

5. The digital X-ray detector of claim 2, wherein:
the active layer is disposed in a vertical direction in correspondence to the side surface of the photoconductive layer,
the vertical transistor further comprises a gate insulating layer disposed between the active layer and the gate electrode, and
the gate electrode is disposed in the vertical direction in correspondence to the side surface of the photoconductive layer.

6. The digital X-ray detector of claim 2, wherein the drain electrode is disposed to overlap with the gate electrode, and the source electrode is disposed to overlap with the gate electrode.

7. The digital X-ray detector of claim 2, wherein the vertical transistor further comprises:
a first passivation layer disposed between the photoconductive layer and the active layer; and
a second passivation layer disposed to cover the gate electrode.

8. The digital X-ray detector of claim 2, wherein:
the drain electrode is disposed on the photoconductive layer to contact the active layer, and
the source electrode is disposed on a lower portion of the side surface of the photoconductive layer to contact the active layer.

9. The digital X-ray detector of claim 1, wherein:
the active layer of the vertical transistor includes low temperature polysilicon, and
a width of a grain boundary of the low temperature polysilicon is longer than a channel length of the active layer.

10. The digital X-ray detector of claim 1, further comprising:
a first protective layer disposed on the second electrode;
a bias electrode disposed on the first protective layer to contact the second electrode; and
a second protective layer disposed on the bias electrode.

11. The digital X-ray detector of claim 1, further comprising:
a plurality of detection circuits electrically connected to a plurality of gate lines, a plurality of data lines and a plurality of bias lines,
wherein each of the plurality of detection circuits comprises the pin diode and the vertical transistor,
wherein the drain electrode of the vertical transistor is electrically connected to a data line among the plurality of data lines,
wherein the source electrode of the vertical transistor is electrically connected to the first electrode of the pin diode, and
wherein the second electrode of the pin diode is electrically connected to a bias line among the plurality of bias lines.

12. The digital X-ray detector of claim 1, wherein:
the active layer of the vertical transistor includes oxide, and
the oxide includes any one of IGZO-based, IGZTO-based, IZO-based, IGO-based, ITO-based, ITZO-based, InO-based, ZnO-based and FIZO-based oxide.
